(19) United States
(12) Patent Application Publication
(10) Pub. No.: US 2009/0023265 A1
(43) Pub. Date: Jan. 22, 2009

(54) ETCHING SOLUTION FOR REMOVAL OF OXIDE FILM, METHOD FOR PREPARING THE SAME, AND METHOD OF FABRICATING SEMICONDUCTOR DEVICE

(76) Inventors: CHANG-SUP MUN, Incheon Metropolitan City (KR); Hyung-Ho Ko, Seoul (KR); Woo-Gwan Shim, Yongin-si (KR); Chang-Ki Hong, Seongnam-si (KR); Sang-Jun Choi, Seoul (KR)

Correspondence Address: Frank Chau, Esq.;F. CHAU & ASSOCIATES, LLC, 130 Woodbury Road, Woodbury, NY, 11797, US

(21) Appl. No.: 12/243,728

(22) Filed: Oct. 1, 2008

Related U.S. Application Data
(62) Division of application No. 11/130,030, filed on May 16, 2005.

(30) Foreign Application Priority Data
May 15, 2004 (KR) 2004/34566

(51) Int. Cl. H01L 21/762; H01L 21/306; H01L 21/02

(52) U.S. Cl. 438/397; 438/756; 438/424; 257/E21.219; 257/E21.546; 257/E21.011

(57) ABSTRACT

Provided are an anionic surfactant-containing etching solution for removal of an oxide film, preparation methods thereof, and methods of fabricating a semiconductor device using the etching solution. The etching solution includes a hydrofluoric acid (HF), deionized water, and an anionic surfactant. The anionic surfactant is a compound in which an anime salt is added as a counter ion, as represented by R₁—OSO₃⁻HA⁺, R₁—CO₂⁻HA⁺,R₁—PO₄²—(HA⁺)₂,(R₁)₂—PO₄—HA⁺, or R₁—SO₃—HA⁺ where R₁ is a straight or branched hydrocarbon group of C₄ to C₂₂ and A is ammonia or amine. The etching solution provides a high etching selectivity ratio of an oxide film to a nitride film or a polysilicon film. Therefore, in a semiconductor device fabrication process such as a STI device isolation process or a capacitor formation process, when an oxide film is exposed together with a nitride film or a polysilicon film, the etching solution can be efficiently used in selectively removing only the oxide film.

### CROSS-REFERENCE TO RELATED APPLICATION

This application is a divisional application of U.S. patent application Ser. No. 11/130,030 filed on May 16, 2005, which in turn claims priority under 35 U.S.C. § 119 to Korean Patent Application No. 2004-34566, filed on May 15, 2004, the disclosures of which are each incorporated by reference herein in their entireties.

### BACKGROUND OF THE DISCLOSURE

1. Field of the Invention

The present invention relates to semiconductor device fabrication. More particularly, the present invention relates to etching solutions for removal of an oxide film, methods for preparing the same, and methods of fabricating a semiconductor device using the etching solution.

2. Description of the Related Art

Semiconductor device fabrication involves a series of processes including deposition, photolithography, etching, ion implantation, and the like. By these processes, various films such as oxide films, nitride films, polysilicon films, and metal films are formed on a wafer. Patterning these films completes the desired shapes of the devices. An etching solution capable of removing film material to be etched with high etching selectivity is required to remove the target film by selective wet etching during the semiconductor device fabrication processes.

Currently available semiconductor device fabrication processes mainly use etching solution such as a buffered oxide etchant (BOE) or a diluted hydrofluoric acid (DHF) to remove an oxide film by wet etching.

However, the time required to etch oxide films using BOE is long, which increases an etch time loss, thereby leads to cost increase and productivity reduction. Furthermore, BOE and DHF have a lower etching selectivity to oxide films, relative to other film materials. In this respect, for example, when an oxide film that is exposed together with a nitride film or a polysilicon film is etched using BOE or DHF, loss of the nitride film or the polysilicon film when it is exposed together with the oxide film increases, which lowers the efficiency of etching in the oxide film.

In particular, for dynamic random access memories (DRAMs), since the semiconductor device is highly integrated and the pattern size decreased, the height of the cylindrical capacitor lower electrode that is used to increase a capacitance increases. Accordingly, the height of the mold oxide film needed to form the cylindrical lower electrode also increases. After an elevated cylindrical lower electrode is formed, removing the mold oxide film by wet etching using a conventional etching solution may cause serious problems.

In more detail, during the drying process after the mold oxide film has been removed by wet etching, “leaning” phenomenon may occur in which the capacitor lower electrodes are attached to each other due to a tilt by the surface tension of water present between the lower electrodes, thereby causing a 2-bit fail. As a result, a technique to prevent the leaning phenomenon of capacitor lower electrodes by forming a support film made of a silicon nitride between the lower electrodes has been suggested and applied to actual processes (see U.S. Patent Application Laid-Open Publication No. 2003/0178728 A1). However, this technique involves several problems in removing the mold oxide film using a conventional etching solution, BOE or DHF. That is, when using BOE as an etching solution for removing a mold oxide film, a crystalline polysilicon constituting lower electrodes may be easily lost by NH₄F constituting BOE. Furthermore, the etch time of the mold oxide film significantly increases. Such an increased etch time may cause the loss of a nitride support film to form for preventing the leaning phenomenon of the lower electrodes. On the other hand, using DHF as an etching solution may cause different etch rates in various locations on the same wafer because of DHF's poor wettability. Furthermore, DHF provides a five fold increase in etch rate to silicon nitride, relative to BOE, thereby causing an increased loss of the silicon nitride.

Meanwhile, when forming an isolation film using shallow trench isolation (STI) technology, a technique that forms a thermal oxide film on the inner wall of the trench and then a thin nitride liner on the thermal oxide film is used to prevent any stress that may be induced during oxidation. After the isolation film is formed, when the oxide film on the surface of the semiconductor substrate is removed by a conventional etching solution, an exposed portion of the thin nitride liner formed in the trench is also removed, thereby generating dents. The size of the dents generated in the nitride liner increases after a subsequent cleaning process. Therefore, unwanted voids may be formed in the trench, thereby deteriorating refresh characteristics.

In this regard, there is a need to develop an etching solution capable of removing an oxide film by wet etching with high etching selectivity so as to minimize the loss of other film materials (e.g., nitride film or polysilicon film) that may be exposed together with the oxide film.

### SUMMARY OF THE INVENTION

An embodiment of the present invention provides an etching solution with a new composition that can provide high etching selectivity to an oxide film so as to minimize the loss of other film materials exposed together with the oxide film.

Another embodiment of the present disclosure also provides a method for preparing an etching solution with a new composition that can provide high etching selectivity to an oxide film.

Another embodiment of the present invention also provides a method of fabricating a semiconductor device, which can easily embody a desired device structure on a semiconductor substrate on which several types of film materials are simultaneously exposed by selectively removing only an oxide film with high etching selectivity.

According to an aspect of the present invention, there is provided an etching solution including a hydrofluoric acid (HF), deionized water, and an anionic surfactant.

The etching solution may include deionized water and a 50% HF solution in a volume ratio of from about 1:1 to about 1,000:1.

In one aspect of the present invention, the anionic surfactant may be one selected from compounds represented by R₁—OSO₃⁻HA⁺, R₁—CO₂⁻HA⁺, R₁—PO₄²⁻(HA⁺)₂, (R₁)₂—PO₄⁻HA⁺, and R₁⁻SO₃⁻HA⁺ where R₁ is a straight or branched hydrocarbon group of C₄ to C₂₂, and A is ammonia or amine, or a combination of two or more of the forgoing compounds.

In another aspect of the present invention, R₁ may be butyl, isobutyl, isooctyl, nonylphenyl, octylphenyl, decyl, tridecyl, lauryl, myristyl, cetyl, stearyl, oleyl, ricinoleyl, or behenyl. A may be ammonia, ethanolamine, diethanolamine, or triethanolamine.

The anionic surfactant may be used in an amount of from about 0.0001 to about 10 wt %, based on the total weight of the etching solution.

According to another aspect of the present invention, there is provided an etching solution including a HF, deionized water, and an anionic surfactant in which an amine salt is added as a counter ion.

According to still another aspect of the present invention, there is provided a method for preparing an etching solution, which includes preparing a diluted hydrofluoric acid (DHF) solution by mixing deionized water and a 50% HF solution and mixing the DHF solution with an anionic surfactant.

According to still another aspect of the present invention, there is provided a method of fabricating a semiconductor device, which includes preparing a semiconductor substrate on which an oxide film and a nitride film are simultaneously exposed and selectively removing only the oxide film using an etching solution of the present invention.

According to still another aspect of the present invention, there is provided a method of fabricating a semiconductor device, which includes preparing a semiconductor substrate on which an oxide film and a polysilicon film are simultaneously exposed and selectively removing only the oxide film using an etching solution of the present invention.

According to still another aspect of the present invention, there is provided a method of fabricating a semiconductor device, which includes preparing a semiconductor substrate on which an oxide film, a nitride film, and a polysilicon film are simultaneously exposed and selectively removing only the oxide film using an etching solution of the present invention.

According to yet another aspect of the present invention, there is provided a method of fabricating a semiconductor device, which includes forming a mask pattern made of a nitride on a semiconductor substrate, forming a trench on the semiconductor substrate by etching the semiconductor substrate using the mask pattern as an etching mask, forming a nitride liner on an inner wall of the trench, forming an oxide film to completely fill the trench on the nitride liner, removing the mask pattern, and cleaning the semiconductor substrate using an etching solution of the present invention in a state wherein at least a portion of the nitride liner is exposed.

According to a further aspect of the present invention, there is provided a method of fabricating a semiconductor device, which comprises forming a first mold oxide film on a semiconductor substrate having a conductive region, forming a support film made of a nitride on the first mold oxide film, forming a second mold oxide film on the support film, forming a storage node hole through which the conductive region is exposed by patterning the second mold oxide film, the support film, and the first mold oxide film, forming in the storage node hole a cylindrical capacitor lower electrode supported by the support film, and selectively removing the first mold oxide film and the second mold oxide film using an etching solution of the present invention.

The etching solution according to the present invention can remove an oxide film with high etching selectivity while minimizing the loss of a silicon nitride film or a polysilicon film. Furthermore, the etching solution according to the present invention can be efficiently used in various semiconductor device fabrication processes requiring a high etching selectivity ratio of an oxide film to a nitride film or a high etching selectivity ratio of an oxide film to a polysilicon film.

### BRIEF DESCRIPTION OF THE DRAWINGS

The above and other features of the present invention will become more apparent by describing in detail exemplary embodiments thereof with reference to the attached drawings in which:

FIG. 1 is a flowchart that illustrates a method for preparing an etching solution according to an exemplary embodiment of the present invention;

FIG. 2 is a graph that illustrates evaluation results for the etch time of an oxide film and the loss of a silicon nitride film with respect to an etching solution according to the present invention;

FIG. 3 is a graph that illustrates evaluation results for the etch time of an oxide film and the loss of a crystalline polysilicon film with respect to an etching solution according to the present invention;

FIG. 4 is a graph that illustrates evaluation results for the etch time of an oxide film and the loss of an amorphous polysilicon film with respect to an etching solution according to the present invention;

FIG. 5 is a graph that illustrates evaluation results for the etch time of an oxide film and the loss of a silicon nitride film with respect to change in content of an anionic surfactant in an etching solution according to the present invention;

FIGS. 6A through 6C are sequential sectional views that illustrate a method of fabricating a semiconductor device according to one embodiment of the present invention; and

FIGS. 7A through 7H are sequential sectional views that illustrate a method of fabricating a semiconductor device according to another embodiment of the present invention.

### DETAILED DESCRIPTION OF THE PREFERRED EMBODIMENT

The present invention may be embodied in many different forms and should not be construed as being limited to embodiments set forth herein. Rather, these embodiments are provided so that this disclosure will be thorough and complete, and will fully convey the scope of the invention to those skilled in the art.

As will be described later in more detail, an etching solution according to the present invention includes a hydrofluoric acid (HF), deionized water, and an anionic surfactant.

Preferably, the etching solution of the present invention includes deionized water and a 50% HF solution in a volume ratio of from about 1:1 to about 1,000:1, and more preferably in a volume ratio of from about 3:1 to about 10:1. Here, as the concentration of the HF in the etching solution increases, an etch time of an oxide film decreases.

The anionic surfactant is used in an amount of from about 0.0001 to about 10 wt %, and preferably from about 0.01 to about 1 wt %, based on the total weight of the etching solution. If the content of the anionic surfactant is too low, the etch rate of other film materials (e.g., polysilicon film or silicon nitride film) exposed on a wafer, in addition to an oxide film to be etched, may increase, and the etching uniformity of the oxide film based on its relative locations on the same wafer may become poor, like the conventional technique. However, the etch rate of the polysilicon film or the silicon nitride film exposed together with the oxide film is not continuously reduced in proportion with the increase in the content of the anionic surfactant in the etching solution of the present invention. The content range of the anionic surfactant that can effect the reduction of the etch rate of the polysilicon film or the silicon nitride film is defined and the detailed description thereof will be described later.

The anionic surfactant may be one selected from compounds represented by the following formulae 1 through 5 in which an amine salt is added as a counter ion, or a combination of two or more of the compounds:

R₁—OSO₃⁻HA⁺ [Formula 1]

R₁—CO₂⁻HA⁺ [Formula 2]

R₁—PO₄²⁻(HA⁺)₂ [Formula 3]

(R₁)₂—PO₄⁻HA⁺, and [Formula 4]

R₁—SO₃⁻HA⁺ [Formula 5]

wherein R₁ is a straight or branched hydrocarbon group of C₄ to C₂₂ and A is ammonia or amine.

Preferably, R₁ is butyl, isobutyl, isooctyl, nonylphenyl, octylphenyl, decyl, tridecyl, lauryl, myristyl, cetyl, stearyl, oleyl, ricinoleyl, or behenyl.

Preferably, A is ammonia, ethanolamine, diethanolamine, or triethanolamine.

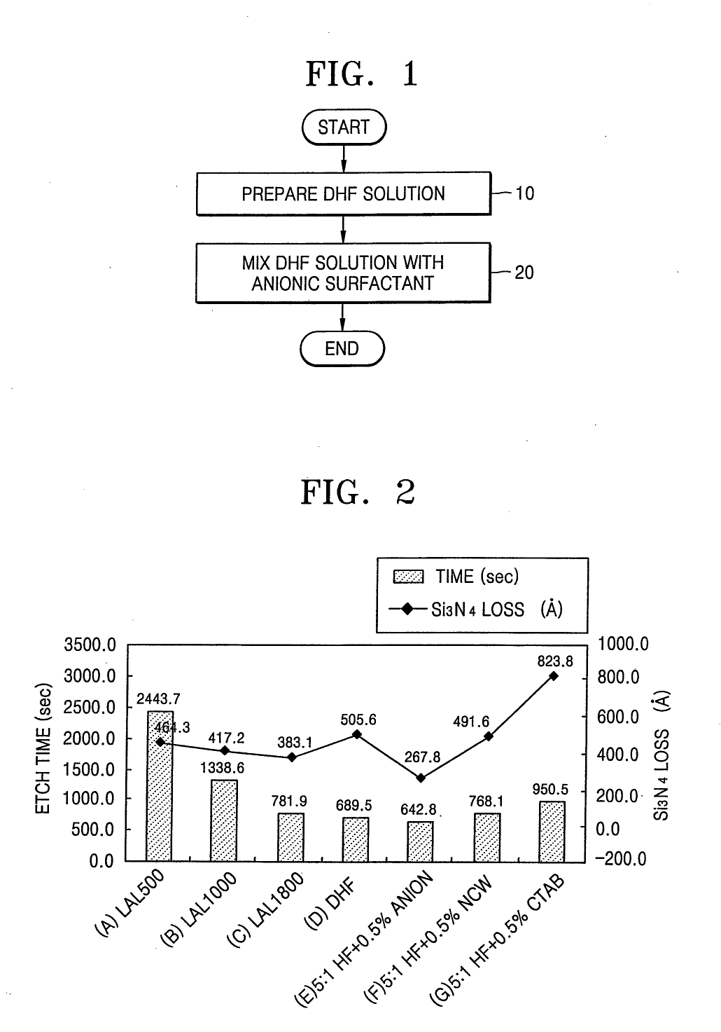

FIG. 1 is a flowchart that illustrates a method for preparing an etching solution according to an exemplary embodiment of the present invention.

Referring to FIG. 1, in operation 10, a diluted hydrofluoric acid (DHF) solution, which is a mixture of deionized water and a HF solution, is first prepared. At this time, when a 50% HF solution is used, the deionized water and the HF solution are mixed in the DHF solution in a volume ratio of from about 1:1 to about 1,000:1, and preferably from about 3:1 to about 10:1.

In operation 20, a mixed solution of the DHF solution with an anionic surfactant is prepared. The mixed solution can be prepared by stirring the DHF solution and the anionic surfactant. The anionic surfactant may be selected from the above-defined compounds. The anionic surfactant is used in an amount of from about 0.0001 to about 10 wt %, preferably from about 0.01 to about 1 wt %, based on the total weight of the etching solution.

Hereinafter, illustrative Experimental Examples for preparation of etching solutions according to the present invention will be described. The present invention will be described more specifically by the following exemplified Experimental Examples. However, the following Experimental Examples are provided only for illustrations and thus the present invention is not limited to or by them.

### Experimental Example 1

0.5 wt % of ammonium lauryl sulfate (ALS) (based on the total weight of an etching solution) used as an anionic surfactant was added to a DHF solution obtained by mixing deionized water and a 50% HF solution in a 5:1 volume ratio to prepare the etching solution.

A borophosphosilicate glass (BPSG) film (9,000 Å) and a plasma-enhanced tetraethylorthosilicate glass (PE-TEOS) film (16,000 Å) were sequentially deposited on a wafer to form an oxide film with a total thickness of 25,000 Å. While the oxide film was etched using the etching solution at room temperature (25° C.), a silicon nitride (Si₃N₄) film was simultaneously etched using the same etching solution to measure the loss of the silicon nitride film.

Measurement results for the etch time of the oxide film and the loss of the silicon nitride film are shown in FIG. 2. In FIG. 2, “(E) 5:1 HF+0.5% anion” represents an etching experiment using the etching solution prepared in Experimental Example 1.

FIG. 2 also shows the etching experiment results for the oxide film and the silicon nitride film using etching solutions prepared in the same manner as in Experimental Example 1 except that a nonionic surfactant and a cationic surfactant are used instead of the anionic surfactant (“(F) 5:1 HF+0.5% NCW” for the nonionic surfactant and “(G) 5:1 HF+0.5% CTAB” for the cationic surfactant, as controls). Here, NCW (Wako Chemical Co. Ltd.) was used as the nonionic surfactant and CTAB (cetyl trimethyl ammonium bromide) was used as the cationic surfactant.

FIG. 2 also shows the etching experiment results for the oxide film and the silicon nitride film using surfactant-free etching solutions as another controls, i.e., (A) LAL500, (B) LAL1000, (C) LAL1800, and (D) DHF (deionized water:50% HF=5:1). Here, (A) LAL500, (B) LAL1000, and (C) LAL1800 are BOE-based etching solutions containing HF/NH₄F as a main component and commercially available from Technosemichem Co. Ltd.

As seen from FIG. 2, the anionic surfactant-containing etching solution according to the present invention exhibited a similar etch time for the oxide film and about 50% reduction in the loss of the silicon nitride film, as compared to (D) DHF solution. Furthermore, the etching solution according to the present invention exhibited a shorter etch time for the oxide film and about 30-50% reduction in the loss of the silicon nitride film, as compared to (A) LAL500, (B) LAL1000, and (C) LAL1800.

### Experimental Example 2

0.1 wt % of ALS (based on the total weight of an etching solution) used as an anionic surfactant was added to a DHF solution obtained by mixing deionized water and a 50% HF solution in a 5:1 volume ratio to prepare the etching solution.

A BPSG film (9,000 Å) and a PE-TEOS film (16,000 Å) were sequentially deposited on a wafer to form an oxide film with a total thickness of 25,000 Å. While the oxide film was etched using the etching solution at room temperature (25° C.), a crystalline polysilicon film was simultaneously etched using the same etching solution to measure the loss of the crystalline polysilicon film. Here, the crystalline polysilicon film was obtained by forming an amorphous polysilicon film followed by annealing at 850° C. for 30 minutes.

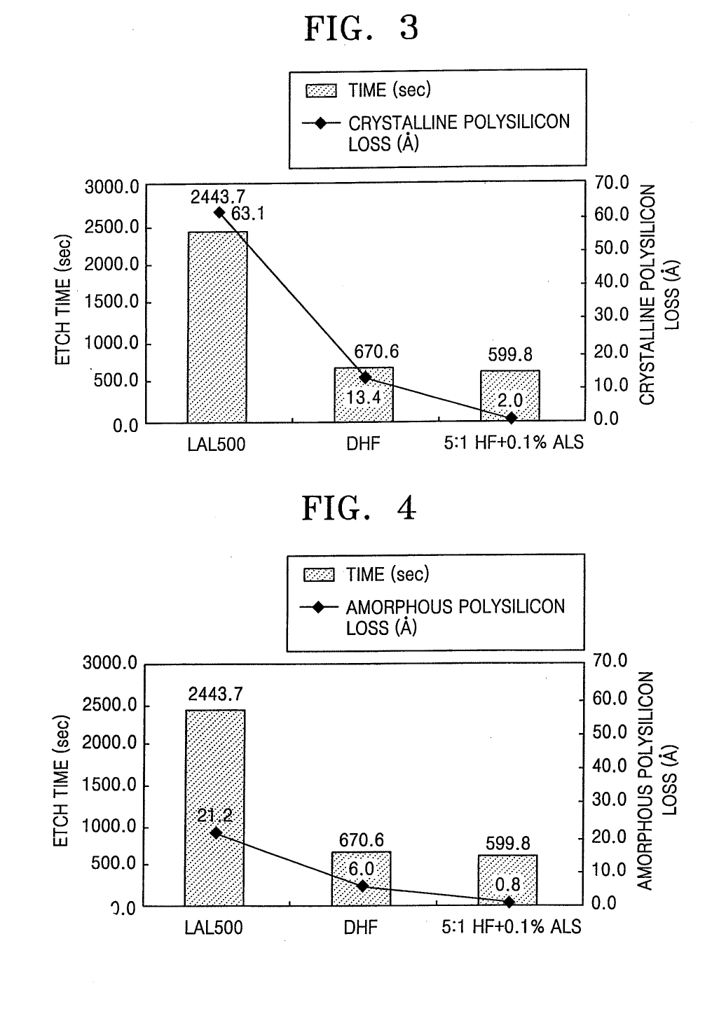

Measurement results for the etch time of the oxide film and the loss of the crystalline polysilicon film are shown in FIG. 3. In FIG. 3, “5:1 HF+0.1% ALS” represents an etching experiment using the etching solution prepared in Experimental Example 2.

FIG. 3 also shows the etching experiment results for the oxide film and the crystalline polysilicon film using surfactant-free etching solutions as controls, i.e., LAL500 and DHF (deionized water:50% HF=5:1).

As seen from FIG. 3, the etching solution containing ALS used as the anionic surfactant according to the present invention exhibited about 3-4% of the loss of the crystalline polysilicon film by LAL500 and about 15% of the loss of the crystalline polysilicon film by DHF.

### Experimental Example 3

This Experimental Example was performed in the same manner as in Experimental Example 2 except that an amorphous polysilicon film was used instead of the crystalline polysilicon film and the results are shown in FIG. 4. The amorphous polysilicon film was obtained in the same manner as that used in Experimental Example 2 and annealing of the amorphous polysilicon film was omitted.

FIG. 4 also shows the etching experiment results for the oxide film and the amorphous polysilicon film using surfactant-free etching solutions as controls, i.e., LAL500 and DHF (deionized water:50% HF=5:1).

As seen from FIG. 4, when the oxide film and the amorphous polysilicon film were simultaneously etched using the etching solution containing ALS as the anionic surfactant according to the present invention, similar results to in FIG. 3 that shows the experimental results for the crystalline polysilicon film were obtained. That is, the etching solution containing ALS used as the anionic surfactant according to the present invention exhibited about 3-4% of the loss of the amorphous polysilicon film by LAL500 and about 13% of the loss of the amorphous polysilicon film by DHF.

### Experimental Example 4

In the Experimental Example, the etch time of an oxide film and the loss of a silicon nitride film with respect to the content of an anionic surfactant in an etching solution according to the present invention were compared and evaluated.

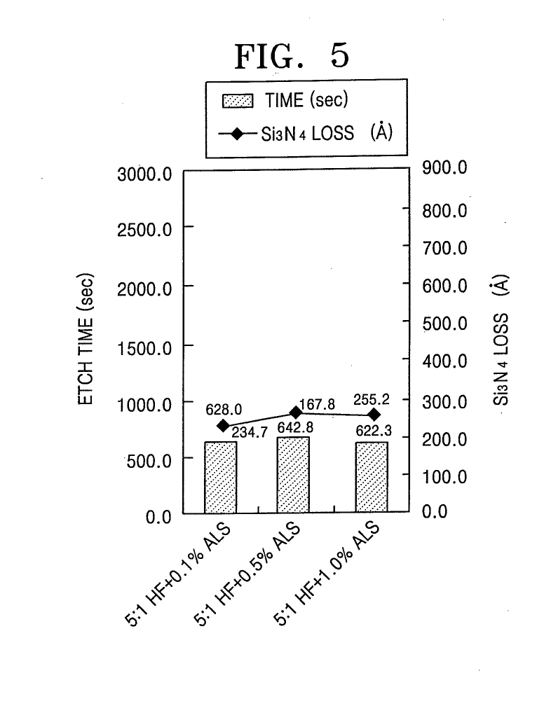

In more detail, an etching solution according to the present invention was prepared in the same manner as in Experimental Example 1 by varying the content of an anionic surfactant in the etching solution (0.1 wt % (5:1 HF+0.1% ALS), 0.5 wt % (5:1 HF+0.5% ALS), and 1.0 wt % (5:1 HF+1.0% ALS), based on the total weight of the etching solution). The etch time of an oxide film and the loss of a silicon nitride film were measured in the same manner as in Experimental Example 1 and the results are shown in FIG. 5.

As seen from FIG. 5, when the content of the anionic surfactant in the etching solution of the present invention changed within a range of from about 0.1 to about 1.0 wt %, no significant changes in the etch time of the oxide film and the loss of the silicon nitride film were observed.

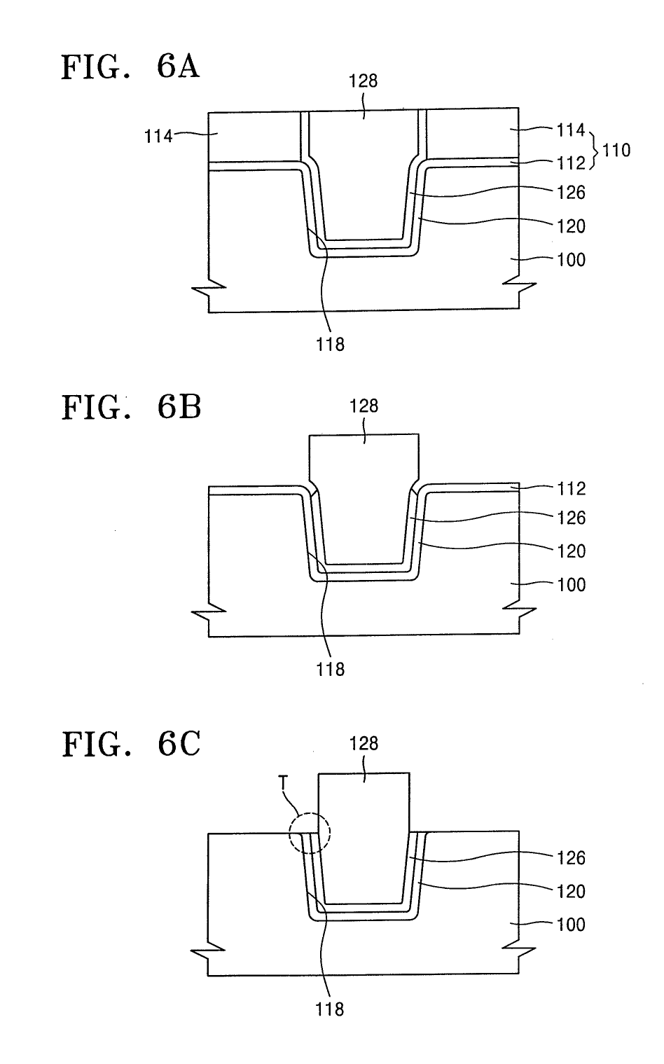

FIGS. 6A through 6C are sequential sectional views that illustrate a method of fabricating a semiconductor device according to a first embodiment of the present invention. In the method of fabricating the semiconductor device according to the first embodiment of the present invention, an example of removal of an oxide film by wet etching using an etching solution according to the present invention in a trench device isolation process is illustrated.

Referring to FIG. 6A, a mask pattern 110 composed of a pad oxide film 112 defining an active region and a mask nitride film 114 is formed on a semiconductor substrate 100. A portion covered by the mask pattern 110 forms an active region and a portion exposed by the mask pattern 110 forms an isolation region. Then, an exposed portion of the semiconductor substrate 100 is etched to a predetermined depth using the mask pattern 110 as an etching mask to form a trench 118. Then, a thermal oxide film 120 is conformally formed in the trench 118 by a thermal oxidation process and a liner 126 made of nitride is formed on the thermal oxide film 120. The liner 126 prevents a defect creation by stress induced in a subsequent oxidation process.

Next, the trench 118 is completely filled by oxide deposition to form an isolation film 128. An upper surface of the mask nitride film 114 is exposed by planarization of the resultant structure.

Referring to FIG. 6B, the mask nitride film 114 is removed by wet etching using phosphoric acid, for example.

Referring to FIG. 6C, the pad oxide film 112 is removed by a cleaning process using an etching solution according to the present invention as described above at about 20 to 70° C., for example at room temperature. When the pad oxide film 112 is removed, a surface portion of the isolation film 128 made of an oxide is also wasted. At this time, even though a portion of the liner 126 made of a nitride as represented by “T” in FIG. 6C is exposed, since the etching solution containing an anionic surfactant according to the present invention can provide high etching selectivity of an oxide film to a nitride film, the loss of the liner 126 can be minimized.

Therefore, the removal of the pad oxide film 112 using the etching solution according to the present invention can efficiently prevent the generation of dents by the loss of the liner 126.

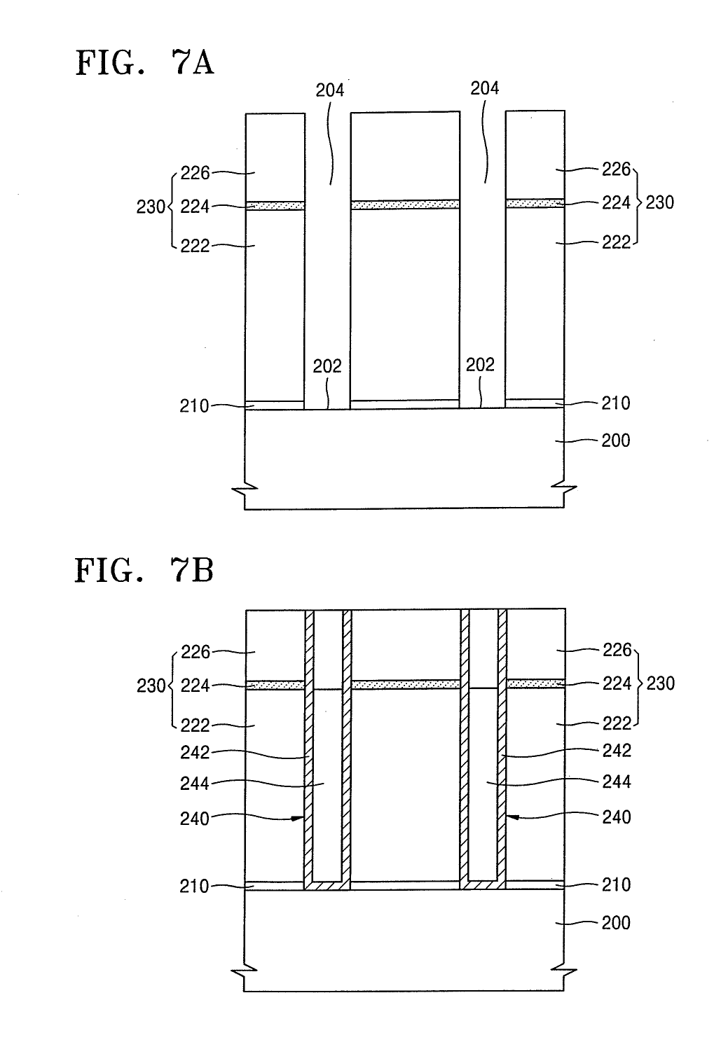

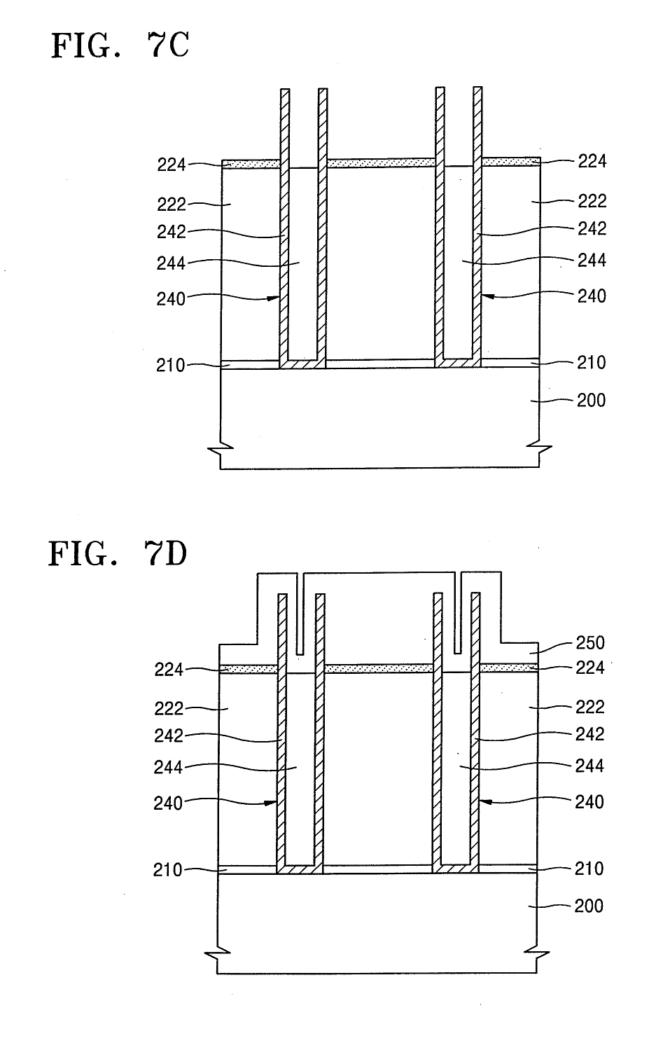

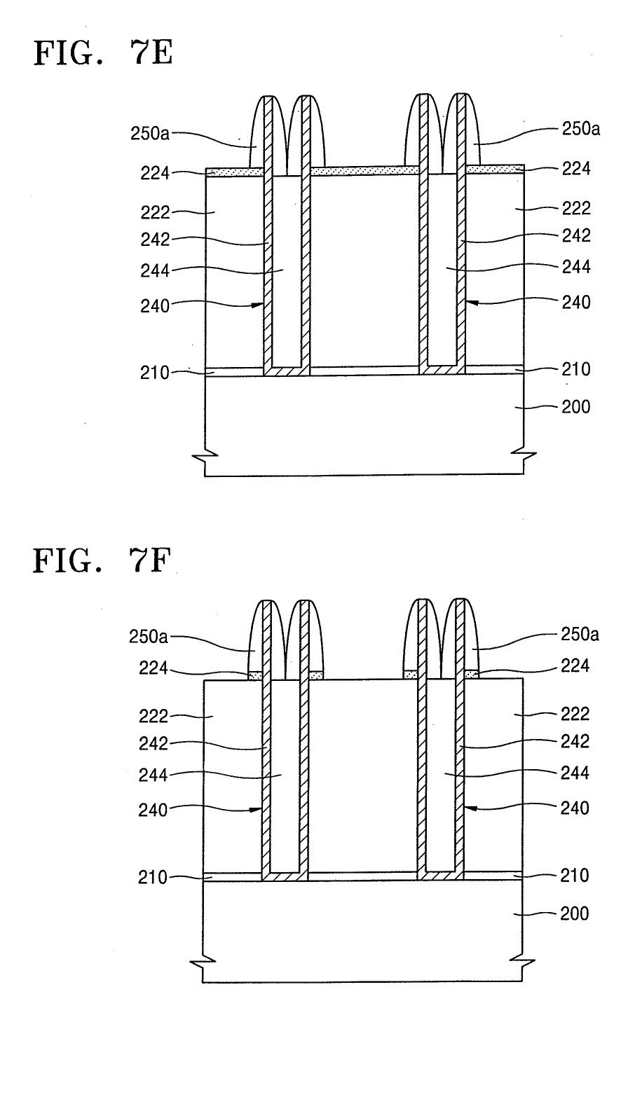

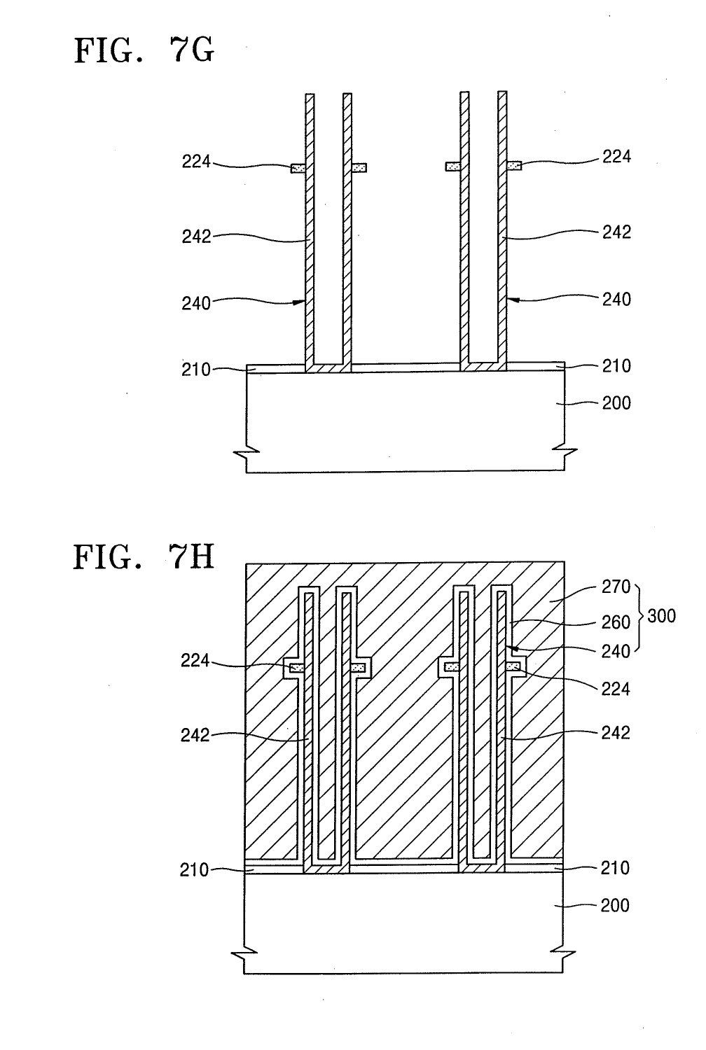

FIGS. 7A through 7H are sequential sectional views that illustrate a method of fabricating a semiconductor device according to a second embodiment of the present invention. In the method of fabricating the semiconductor device according to the second embodiment of the present invention, an example of removal of an oxide film by wet etching using an etching solution according to the present invention in formation of a capacitor for a highly integrated semiconductor memory device will be illustrated.

Referring to FIG. 7A, to form a capacitor having an integrated OCS (one cylinder stack) structure, although not shown, an isolation film, a gate, a source/drain region, a plurality of contact pads, a bit line, and the like are first formed on a semiconductor substrate 200. Then, an etch stop film 210, a first mold oxide film 222, a support film 224, and a second mold oxide film 226 are sequentially formed on the semiconductor substrate 200 and patterned by dry etching using the etch stop film 210 to form a mold dielectric film pattern 230 defining a storage node hole 204 through which a conductive region 202 on the semiconductor substrate 200 is exposed.

The first mold oxide film 222 and the second mold oxide film 226 can be made of various types of oxides. For example, the first mold oxide film 222 and the second mold oxide film 226 may be made of BPSG or PE-TEOS. The support film 224 is made of a silicon nitride to prevent falling down of cylindrical lower electrodes that will be formed in a subsequent process. Here, the support film 224 can be variously disposed according to a user's purpose. For example, the support film 224 can be formed in such a way to extend along a gate direction or a bit line direction.

Referring to FIG. 7B, a conductive layer 242 made of a doped polysilicon is formed in the storage node hole 204 and a first oxide film 244 completely filling the storage node hole 204 is then formed. The resultant structure is planarized to form an isolated lower electrode 240 for each cell. For example, the first oxide film 244 may be made of one of SOG (spin on glass), BPSG, USG (undoped silicate glass), and PE-TEOS, which are excellent in filling property.

Referring to FIG. 7C, the second mold oxide film 226 and a portion of the first oxide film 244 are removed by wet etching using an etching solution according to the present invention as described above at from about 20 to about 70° C., for example at room temperature, to expose the upper surfaces of the support film 224 and the lower electrode 240.

Referring to FIG. 7D, a second oxide film 250 covering the exposed portions of the lower electrode 240, the first oxide film 244, and the support film 224 is formed. For example, the second oxide film 250 may be an USG film.

Referring to FIG. 7E, a second oxide film spacer 250a is formed on an upper sidewall of the lower electrode 240 by an etch-back process of the second oxide film 250. As a result, a portion of the support film 224 near the second oxide film spacer 250a is again exposed.

Referring to FIG. 7F, the exposed portion of the support film 224 near the second oxide film spacer 250a is removed by etching.

Referring to FIG. 7G, the first mold oxide film 222, the second oxide film spacer 250a, and the first oxide film 244 are completely removed by wet etching using an etching solution according to the present invention as described above. At this time, an anionic surfactant contained in the etching solution according to the present invention serves to protect the surface of the lower electrode 240 made of polysilicon and the surface of the support film 224 made of silicon nitride. Therefore, the loss of the lower electrode 240 and the support film 224 can be minimized during etching the first mold oxide film 222, the second oxide film spacer 250a, and the first oxide film 244 using the etching solution according to the present invention.

Referring to FIG. 7H, a dielectric film 260 and an upper electrode 270 are sequentially formed on the lower electrode 240 to complete a capacitor 300.

As described above in the method of fabricating the semiconductor device according to the second embodiment of the present invention, by using an etching solution according to the present invention to form a capacitor for a highly integrated semiconductor memory device, the loss of a supporter made of a silicon nitride to prevent the leaning phenomenon of elevated lower electrodes and the lower electrodes made of polysilicon and supported by the supporter can be minimized. At the same time, an elevated mold oxide film can be efficiently removed with high etching selectivity. In this respect, an etching solution according to the present invention can be efficiently used in semiconductor memory device fabrication for ensuring a sufficient cell capacitance in a limited area.

An etching solution according to the present invention includes HF, deionized water, and an anionic surfactant. When an oxide film is etched using the etching solution according to the present invention, the anionic surfactant contained in the etching solution serves to protect the surface of a nitride film or a polysilicon film, thereby increasing the etching selectivity of the oxide film. Therefore, the etching solution according to the present invention can etch an oxide film with high etching selectivity while minimizing the loss of a silicon nitride film or a polysilicon film, unlike the conventional etching solution, such as BOE or DHF, as used for removing oxide film in the conventional process. In this respect, the etching solution according to the present invention can be efficiently used in various semiconductor device fabrication processes requiring a high etching selectivity ratio of an oxide film to either a nitride film or a polysilicon film. In particular, the use of the etching solution according to the present invention in removing an oxide film from a semiconductor substrate during a STI device isolation process can prevent deterioration of device refresh characteristics. Furthermore, in fabricating a capacitor for a highly integrated semiconductor memory device, the use of the etching solution according to the present invention to remove an elevated mold oxide film around an elevated cylindrical capacitor lower electrode and a supporter supporting the lower electrode can efficiently remove only the oxide film with high etching selectivity while minimizing the loss of the lower electrode and the supporter.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of fabricating a semiconductor device, which comprises:
preparing a semiconductor substrate on which an oxide film and a nitride film are simultaneously exposed; and selectively removing only the oxide film using an etching solution comprising hydrofluoric acid, deionized water and an anionic surfactant.

2. The method of claim 1, which comprises maintaining the etching solution at a temperature of from about 20 to about 70° C. during removing the oxide film.

3. A method of fabricating a semiconductor device, which comprises:
preparing a semiconductor substrate on which an oxide film and a polysilicon film are simultaneously exposed; and selectively removing only the oxide film using an etching solution comprising hydrofluoric acid, deionized water and an anionic surfactant.

4. The method of claim 3, wherein the etching solution is maintained at a temperature of from about 20 to about 70° C. during removing the oxide film.

5. A method of fabricating a semiconductor device, which comprises:
preparing a semiconductor substrate on which an oxide film, a nitride film, and a polysilicon film are simultaneously exposed; and selectively removing only the oxide film using an etching solution comprising hydrofluoric acid, deionized water and an anionic surfactant.

6. The method of claim 5, wherein the etching solution is maintained at a temperature of from about 20 to about 70° C. during removing the oxide film.

7. A method of fabricating a semiconductor device, which comprises:
forming a mask pattern made of a nitride on a semiconductor substrate; forming a trench on the semiconductor substrate by etching the semiconductor substrate using the mask pattern as an etching mask; forming a nitride liner on an inner wall of the trench; forming an oxide film to completely fill the trench on the nitride liner; removing the mask pattern; and cleaning the semiconductor substrate using the etching solution of claim 1 in a state wherein at least a portion of the nitride liner is exposed.

8. The method of claim 7, wherein the operation of cleaning the semiconductor substrate is carried out at a temperature of from about 20 to about 70° C.

9. A method of fabricating a semiconductor device, which comprises:
forming a first mold oxide film on a semiconductor substrate having a conductive region; forming a support film comprises a nitride on the first mold oxide film; forming a second mold oxide film on the support film; forming a storage node hole through which the conductive region is exposed by patterning the second mold oxide film, the support film, and the first mold oxide film; forming in the storage node hole a cylindrical capacitor lower electrode supported by the support film; and selectively removing the first mold oxide film and the second mold oxide film using the etching solution of claim 1.

10. The method of claim 9, wherein the capacitor lower electrode comprises a doped polysilicon.

11. The method of claim 9, wherein the operation of removing the first mold oxide film and the second mold oxide film is carried out at a temperature of from about 20 to about 70° C.
